(19) United States
(12) Patent Application Publication
(10) Pub. No.: US 2005/0180522 A1
(43) Pub. Date: Aug. 18, 2005

(54) Method and system for high bandwidth-efficiency communications using signals having positive entropy

(76) Inventor: Thomas L. Carroll, Alexandria, VA (US)

Correspondence Address: Associate Counsel (Patents), Code 1008.2, Naval Research Laboratory, Washington, DC, 20375-5000, US

(21) Appl. No.: 10/779,553

(22) Filed: Feb. 13, 2004

(51) Int. Cl. H04L 27/20; H03D 1/00

(52) U.S. Cl. 375/295; 375/340

(57) ABSTRACT

A communications device includes a symbol encoder for receiving data comprising a symbol and for receiving a first signal having a positive entropy. The symbol encoder adds to the first signal a plurality of delayed versions of the first signal. Each delayed version of the plurality of delayed versions has a plurality of available values. The symbol is represented by a set of delay values, a delay value of the set of delay values including an available value of the plurality of available values for the each delayed version of the plurality of delayed versions. The communications device also includes a transmitter for receiving the encoded data from the symbol encoder and for transmitting the encoded data. For example, the first signal having positive entropy includes a chaotic signal, noise signal, or a positive entropy, baseband signal modulated onto a positive entropy signal having a higher frequency than the baseband signal. For example, the chaotic signal includes a Lorenz system-generated chaotic signal or a Rossler system-generated chaotic signal. The communications device supports bandwidth-efficient transmission in communications media.

### FIELD OF THE INVENTION

The present invention relates generally to a method and/or system for high bandwidth-efficiency communications using a broadband signal, and more particularly to a method and/or system for high bandwidth-efficiency communications using a signal having a positive entropy.

### BACKGROUND OF THE INVENTION

Conventionally, in communications, a baseband signal is modulated onto a periodic carrier signal. The baseband signal is a signal with a frequency spectrum from zero to a band-limited value. Typically, the range of frequencies in the frequency spectrum is dependent on the information to be transmitted. Because the carrier signal is periodic, it has zero entropy and contains no information. One may find the information capacity of the signal by considering only the baseband signal. Information capacity is understood as described below.

Most research in the field of nonlinear dynamics on methods of improving communication is directed to improving the power efficiency of signals, where power efficiency is defined as the energy to send one bit of information normalized by the noise power per unit of frequency (i.e., noise power spectral density). In a few cases, power efficiencies of communications methods developed using ideas from nonlinear dynamics approach the power efficiency of existing communications methods, but most new methods based on nonlinear dynamics are not very power efficient. See, e.g., A. Abel, W. Schwartz, and M. Goetz, “Noise Performance of Chaotic Communication Systems,” IEEE Transactions on Circuits and Systems Part I, vol. 47, December pp. 1726-1732, 2000, C. Williams, “Chaotic Communications over Radio Channels,” IEEE Transactions on Circuits and Systems Part I. Fundamental Theory and Applications, vol. 48, December pp. 1394-1404, 2001, and M. P. Kennedy, G. Kolumban, and G. Kis, “Chaotic Modulation for Robust Digital Communications over Multipath Channels,” International Journal of Bifurcations and Chaos in Applied Science and Engineering, vol. 10, 2000 pp. 695-7 #18, 2000, each incorporated herein by reference.

Binary phase shift keying (“BPSK”) has the highest power efficiency theoretically possible for antipodal signals, such as sines and cosines. See, e.g., B. Sklar, Digital Communications, Fundamentals and Applications. Englewood Cliffs, N.J.: Prentice Hall, 1988, incorporated herein by reference. In BPSK, the phase of a periodic carrier signal is switched to +180 or −180 degrees to represent binary 1 or 0. While BPSK is very power efficient, it requires a lot of bandwidth to transmit each bit of information, so it is not very bandwidth-efficient. Williams discloses that because chaotic signals have structures that are preserved by all but the most extreme filtering, chaotic signals may be useful for communicating with high bandwidth efficiency.

T. M. Cover et al., Elements of Information Theory. New York: Wiley, 1991 (“Cover et al.”), S. Hayes et al., “Experimental Control of Chaos for Communication,” Physical Review Letters, vol. 73, September pp. 1781-1784, 1994 (“Hayes et al.”), M. S. Baptista et al., “Controlling transient dynamics to communicate with homoclinic chaos,” Chaos, vol. 13, September pp. 921-925, 2003, M. S. Baptista et al., “Conditions for efficient chaos-based communication,” Chaos, vol. 13, March pp. 145-150, 2003, E. M. Bollt, “Review of chaos communication by feedback control of symbolic dynamics,” International Journal of Bifurcations and Chaos, vol. 13, February pp. 269-285, 2003, S. D. Pethel et al., “Information flow in chaos synchronization: Fundamental tradeoffs in precision, delay, and anticipation,” Physical Review Letters, vol. 90, June pp. 254101, 2003, each incorporated herein by reference, generally discuss the application of signals such as chaos to communications. Hayes et al. discloses that chaotic carriers may be utilized as information carriers because of their positive entropy, and several groups have attempted to apply some of Hayes et al.' ideas. Entropy as it relates to signals is understood as follows. If the probability of a signal having a certain value x is p(x), then the entropy of the signal is −Σ[p(x)*log(p(x))]. See, e.g., Cover et al. The entropy is related to the amount of information created in a signal. For instance, the entropy of a sine wave is zero because the signal is the same for every cycle.

U.S. Pat. No. 3,925,730 to de Rosa, incorporated herein by reference, discloses a prior art secure communications system that antedates Hayes et al. de Rosa discloses a plurality of noise signals each having a predetermined time delay with respect to each other that are produced from atmospheric noise or man-made noise. Each of the noise signals is coupled to different time coincident devices. The intelligence signal is quantized and the output levels therefrom are coupled to different ones of the coincident devices to select a noise signal to represent the quantized level. The selected noise signals are transmitted to a receiver in which replicas of the noise signals are generated. A plurality of correlation detectors each responsive to a given noise signal and its replica are provided in the receiver to recover the intelligence signal. However, de Rosa's system lacks practical scalability of its symbol set size. More specifically, de Rosa's system includes one AND gate for a given input data symbol. There is a practical limit to the number of delays that can be added pursuant to de Rosa's disclosure because after a point, the chaotic carrier signal repeats or substantially conforms to an earlier pattern. After that point, no additional, distinguishable symbols can be added to de Rosa's symbol set.

U.S. Pat. No. 4,285,048 to Casasent et al., incorporated herein by reference, discloses a correlation method and apparatus for electrical signal transmission and reception of coded waveforms are disclosed which makes use of a coordinate transformation of the original waveform prior to transmission, effecting an inverse coordinate transformation upon reception and then correlating the resultant waveform with the original waveform. More particularly, the coordinate transformation and its inverse comprises a non-linear transformation preferably of the logarithmic type which when utilized in an electro-optical signal processor of a radar system, for example, provides Doppler invariant output data, as well as additional noise immunity. Casasent et al. fails to teach or suggest any application of the disclosure to anything other than traditional signals having zero entropy.

### BRIEF SUMMARY OF THE INVENTION

An embodiment of the present invention is directed to a communications device that includes a symbol encoder for receiving data comprising a symbol and for receiving a first signal having a positive entropy. The symbol encoder adds to the first signal a plurality of delayed versions of the first signal. Each delayed version of the plurality of delayed versions has a plurality of available values. The symbol is represented by a set of delay values, a delay value of the set of delay values including an available value of the plurality of available values for the each delayed version of the plurality of delayed versions. The communications device also includes a transmitter for receiving the encoded data from the symbol encoder and for transmitting the encoded data. For example, the first signal having positive entropy includes a chaotic signal, noise signal, or a positive entropy, baseband signal modulated onto a positive entropy signal having a higher frequency than the baseband signal. For example, the chaotic signal includes a Lorenz system-generated chaotic signal or a Rossler system-generated chaotic signal.

An embodiment of the present invention is directed to a communications device for receiving encoded data. The communications device includes a receiver for receiving a first signal having positive entropy added to a plurality of delayed versions of the first signal. Each delayed version of the plurality of delayed versions includes a plurality of available values. Encoded data includes a symbol, the symbol being represented by a plurality of delay values. A delay value of the plurality of delay values includes an available value of the plurality of available values for the each delayed version of the plurality of delayed versions. The communications device includes a symbol decoder for receiving the encoded data from said receiver. The symbol decoder sums a second signal, substantially similar to the first signal, and a plurality of reference delays. The symbol decoder maximizes a cross-correlation between the encoded data and the sum of the second signal and the plurality of reference delays. For example, the first signal having positive entropy includes a chaotic signal, noise signal, or a positive entropy, baseband signal modulated onto a positive entropy signal having a higher frequency than the baseband signal. For example, the chaotic signal includes a Lorenz system-generated chaotic signal or a Rossler system-generated chaotic signal. In an alternate embodiment of the invention, the communications device further includes an equalizer communicating with the receiver and with the symbol decoder.

In an additional embodiment of the instant invention, a communications device for receiving encoded data includes a receiver for receiving a first signal having positive entropy added to a plurality of delayed versions of the first signal. Each delayed version of the plurality of delayed versions includes a plurality of available values. Encoded data includes a symbol. The symbol is represented by a plurality of delay values. A delay value of the plurality of delay values includes an available value of the plurality of available values for the each delayed version of the plurality of delayed versions. The communications device includes a symbol decoder for receiving the encoded data from the receiver. The symbol decoder sums a third signal, being a weighted version of the first signal, and a plurality of weighted reference delays. The symbol decoder performs a least squares fit between the encoded data and the sum of the third signal and the plurality of weighted reference delays. For example, the first signal having positive entropy includes a chaotic signal, noise signal, or a positive entropy, baseband signal modulated onto a positive entropy signal having a higher frequency than the baseband signal. For example, the chaotic signal includes a Lorenz system-generated chaotic signal or a Rossler system-generated chaotic signal. In an alternate embodiment of the present invention, the communications device further includes an equalizer communicating with the receiver and with the symbol decoder.

An embodiment of the present invention is directed to a communications method that includes the following steps. A first signal having a positive entropy is provided, and a plurality of delayed versions of the first signal is provided. Each delayed version of the plurality of delayed versions includes a plurality of available values. Data including a symbol is encoded by representing the symbol as a plurality of delay values. Each of the plurality of delay values includes an available value of the plurality of available values for each delayed version of the plurality of delayed versions. The encoded data is transmitted across a communications channel. In another embodiment of the invention, the first signal having positive entropy and the plurality of delayed versions of the first signal are summed. The plurality of delayed versions of the first signal includes the plurality of delay values for the symbol. In still another embodiment, the encoded data is decoded by identifying each transmitted, delayed version of the plurality of delayed versions of the first signal and determining a transmitted delay value of the plurality of delay values for each identified delayed version. For example, the first signal includes a chaotic signal, a noise signal, or a positive entropy, baseband signal modulated onto a positive entropy signal having a higher frequency than the baseband signal.

In yet another embodiment of the invention, the decoding step includes the following steps. A second signal substantially similar to the first signal is generated. The second signal and a plurality of reference delays are summed. A cross-correlation is maximized between the encoded data and the sum of the second signal and the plurality of reference delays. In another embodiment, the plurality of reference delays is compensated for degradation by the communications channel of the plurality of delayed versions of the first signal.

In an alternate embodiment of the present invention, the decoding step includes the following steps. A weighted third signal substantially similar to the first signal is generated. The weighted third signal and a plurality of weighted reference delays are summed. A least squares fit is peformed between the encoded data and the sum of the third signal and the plurality of weighted reference delays. In still another embodiment, the plurality of weighted reference delays is compensated for degradation by the communications channel of the plurality of delayed versions of the first signal.

An embodiment of the invention is directed to a bandwidth-efficient communications method and/or system that takes advantage of the properties of positive entropy signals. The embodiment uses a carrier signal that has a positive entropy to add information to the transmission thereof. The information capacity of the modulated carrier is greater than it would be for a purely periodic carrier. The signal that functions as a carrier has a positive entropy, increasing the amount of information that may be transmitted on a signal. The embodiment of the delay communication method and system makes use of the positive entropy of the carrier signal as well as the entropy of the modulating signal.

An embodiment of the present invention supports bandwidth-efficient transmission in communications media, wherein information is transmitted in a fixed bandwidth, such as in data networks using either wires or fiber optics, in land-line communications systems, e.g., telephone networks, that operate over wires or fiber optics, and in wireless communications networks. Bandwidth efficiency in such networks facilitates use of data-hungry applications such as video-on-demand and Internet access. Such bandwidth efficiency also reduces time required for data transfer, which, for example, makes unauthorized detection of the data transmission more difficult than it otherwise would be.

### BRIEF DESCRIPTION OF THE DRAWINGS

FIG. 1 is a graph of a power spectrum of a first sample chaotic map.

FIG. 2 is a graph of a sample cross-correlation between a sample delay communication signal and a sample set of reference signals.

FIG. 3 is a graph of a power spectrum of a second sample chaotic map.

FIG. 4 is a graph of a power spectrum of a third sample chaotic map.

FIG. 5 is a graph comparing bandwidth efficiencies of two quadrature amplitude modulation communications systems with bandwidth efficiencies of three communications systems according to the invention.

FIG. 6 is a block diagram of a communications system according to the invention.

FIG. 7 is a schematic diagram of an bandpass filter according to the invention.

FIG. 8 is a flow chart of a method according to the invention.

FIG. 9 is a block diagram of a computer system for executing computer-readable method steps according to the invention.

### DETAILED DESCRIPTION OF THE INVENTION

A delay communication method and system according to the invention is as follows. A time series is taken from a system having a positive entropy, such as a chaotic map or a noise signal.

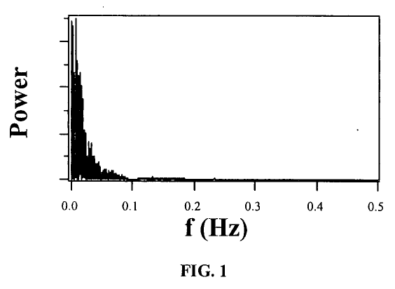

An illustrative chaotic map is
xₙ₊₁₀=μxₙ mod1 (1).
where μ=2.1. As part of the time series generation, this map is updated, for example, once every ten iterations in order to produce a low frequency signal x(t). As described below, this low frequency signal is used to modulate a carrier. FIG. 1 shows the power spectrum of the output from the map of Eq. (1), which has a bandwidth of approximately 0.1 Hz.

Data, or information, is encoded by adding to x(t) n delayed versions of x(t). Each of the n delayed signals may have m delay values. The number of delay values is upper-bounded by inter-symbol interference. The signal that is transmitted is

$${ξ}_{t} ( t ) = x ( t ) + {\sum }_{i = 1}^{n} x ( t + {τ}_{i} ) \qquad ( 2 )$$

where each τᵢ can have m values. The information to be encoded and transmitted includes symbols. For example, a text message includes alphanumeric and punctuation symbols. More specifically, each symbol in a symbol set for an n delay system is represented by a set of n delay values of n delayed versions of x(t). For instance, in a symbol set for a three delay system, each symbol is represented by the set of three delay values, the first delay value is a value of the function x(t+τ₁); the second delay value is a value of the function x(t+τ₂); the third delay value is a value of the function x(t+τ₃).

The ordering of the delay signals is not distinguishable, and no two delay signals are allowed to have the same delay value, so the total number of symbols in a symbol set for an n delay communication system is

$${N}_{s} = \frac{m ( m - 1 ) ( m - 2 ) … ( m - n + 1 )}{n !} \qquad ( 3 )$$

At the receiver, the transmitted signal is cross-correlated with a set of reference signals

$${ξ}_{ref} ( t ) = x ( t ) + {\sum }_{j = 1}^{n} x ( t + {τ}_{j} ) \qquad ( 4 )$$

where x(t) is identical to, or substantially similar to, the x(t) signal in the transmitter. Cross-correlation is understood as follows. For two discrete signals x(i) and y(i), cross-correlation is C(τ)=Σ{[x(i+τ)−x_ave]*y(i)−y_ave]}/{Σ[(x(i)−x_ave)\hat{ }2]*Σ[(y(i)−y_ave)\hat{ }2]}, where x_ave is the average value of x(i), where y_ave is the average value of y(i), and where τ is a delay. For continuous signals, the summations are replaced by integrals. Alternate definitions of cross-correlation omit the denominator of C(τ), which in the cross-correlation formula above normalizes the cross-correlation so that the largest possible value is one.

The similarity of the transmitted and reference signals must be sufficient to determine accurately the encoded data pursuant to the instant invention. A communications system having non-identical transmitted and reference signals has the same effect as a communications system having identical transmitted and reference signals, where the transmitted signal, for example, is corrupted by noise. Such corruption reduces optimum bandwidth efficiency.

The cross-correlation is maximized when ξₜ(t)=ξ_{ref}(t), which is true when each signal uses the same set of delays. Cross-correlation between transmitted and reference signals, for example, is used to identify which combination of delay values was used in the transmitted signal, to determine which symbol was transmitted.

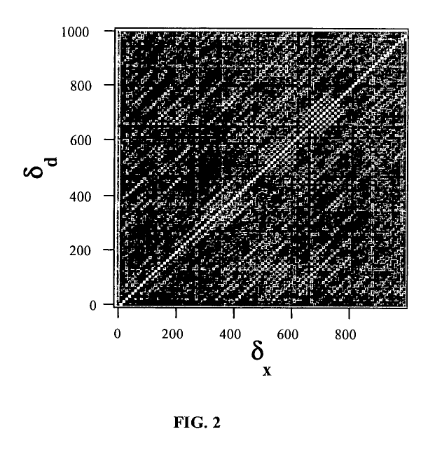

FIG. 2 demonstrates that cross-correlation is maximized when ξₜ(t)=ξ_{ref}(t). For FIG. 2, by way of illustration, the number of delays n=1 and the signal x(t) is generated by the map of Eq. (1) with μ=2.1. On the horizontal axis of FIG. 2 is plotted the delay value m. The vertical axis of FIG. 2 is the delay value for the reference signal. So, δₓ is the delay value in timesteps of the delayed signal added to an undelayed signal, as in Eq. (2), while δ_{d} is the delay value of the reference signal. FIG. 2 shows the cross-correlation between transmitted and reference signals, with white being 1 and black being 0. It can be seen in FIG. 2 that the cross-correlation is maximized when the reference delay is equal to the transmitted delay. That is, the largest cross-correlation occurs when the transmitted and reference signals have the same, or substantially the same, delay value.

Information capacity is the largest amount of information that a signal can carry. Entropy is an upper bound on information capacity. That is, the information capacity C of a signal is less than or equal to the entropy H of the signal. This delay communication method should work for any broad band signal. However, for simplicity of illustration, signals having positive entropies that are easily calculated are used. So, for this example, 1-dimensional chaotic maps are used. However, in practice, multi-dimensional chaotic maps are alternatively beneficially used.

In order to calculate the entropy of a signal, the generating partition of the signal must be known. In general, finding the generating partition is an unsolved problem, but for a 1-dimensional map, the generating partition is defined by the set of critical points of the map. Thus, for the map of Eq. (1), the range of the map may be divided into three regions: 0<xₙ≦1/2.1, 1/2.1<xₙ≦2/2.1, and 2/2.1<xₙ. If pᵢ(xₙ) is the probability that xₙ falls into region i, then

$$H = - {\sum }_{i = 1}^{3} {p}_{i} ( {x}_{n} ) log [ {p}_{i} ( {x}_{n} ) ] .$$

Using the logarithm base 2, the entropy of the signal x(t) from the map of Eq. (1) with μ=2.1 is 1.18 bits. The entropy of the map signal is an upper bound for the information capacity C of the map signal, and the information capacity C indicates the minimum signal to noise ratio for which error free communication is possible:

$$C = \frac{1}{2} log ( 1 + \frac{S}{N} ) \qquad ( 5 )$$

where S/N means signal power divided by noise power. Using the carrier signal from the map of Eq. (1) with the number of delays n=3 and the number of possible delay values m=100, (where, in this example, delay values are spaced every 100 points), Eq. (3) gives 161,700 possible combinations of delay values, or 17.3 bits of information. When Gaussian white noise (with the same bandwidth as the map signal) is added to the delay communication signal described here, and the length of each data interval is L=100, error free communication for μ=2.1 is possible for an S/N of 277, or an E_{b}/N₀ of 34 dB.

The information capacity C of a signal is also limited by its bandwidth. Bandwidth efficiency in bits/second/Hz is used to describe this capacity, or C/W, where W is the signal bandwidth. For a simulated signal in which noise bandwidth=signal bandwidth=simulation bandwidth,

$$\frac{{E}_{b}}{{N}_{0}} = \frac{W}{C} ( {2}^{C / W} - 1 ) \qquad ( 6 )$$

where E_{b}/N₀ is the minimum energy in one bit normalized by the noise power spectral density for error free communication. For our map signal of Eq. (1), if each iteration represents a time step of 1 s, then W=0.1 Hz. If A_{N} is the noise amplitude, then N₀=A_{N}²/W. For a signal amplitude Aₛ and a time of T_{b} for 1 bit, E_{b}=Aₛ² T_{b}. The bandwidth efficiency for the signal generated by the map of Eq. (1) is 17.3 bits/100 s/0.1 Hz=1.73 b/s/Hz. From Eq. (6), the bandwidth efficiency C/W for E_{b}/N₀=34 dB is 15 b/s/Hz. The calculated bandwidth efficiency C/W is the maximum possible bandwidth efficiency for error free communication, and it is greater than our value of 1.73 b/s/Hz.

Typically, a signal such as the map signal above is modulated onto a periodic carrier for transmission. If a carrier is used which is not periodic, but has a positive entropy, then the information capacity C of the transmitted signal can be increased.

To generate an illustrative carrier signal y(t), the following map is used.

$${y}_{n + 1} = h [ g ( {y}_{n} ) {y}_{n} ] \\ g ( y ) = \{ \begin{matrix}1.3 & x < 0.5 \\ - 0.7 & x \geq 0.5\end{matrix} \} \\ h ( y ) = \{ \begin{matrix} & ⋮ \\ y - 2 & y > 1 \\ y & - 1 \leq y \leq 1 \\ y + 2 & y < - 1 \\ & ⋮\end{matrix} \} \qquad ( 7 )$$

where h(y) acts like a modulus to keep yₙ₊₁ between −1.0 and 1.0. The calculated entropy of the signal y(t) is 1.58 bits.

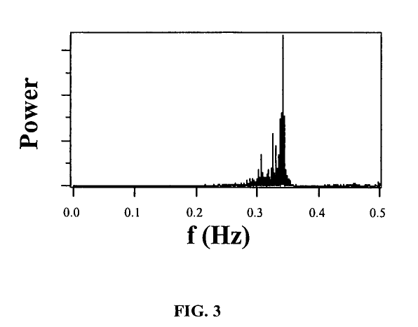

To modulate this carrier, the signal x(t) from the map of Eq. (1) is used. FIG. 3 is the power spectrum from y(t) from the map of Eq. (7).

The signal y(t) from the map of Eq. (7) is used by itself with a delay communication method and system having, for example, n=3 delays and m=100 possible values. The delay values used are, for instance, every 100 points (i.e., delay values of 100, 200, etc). For this example, 100 points are used for each bit of information; so, the bit duration is 100 s. The signal y(t) is filtered so that only frequencies between, for example, 0.27 and 0.37 Hz are passed, and the added Gaussian white noise is also filtered so that only these frequencies are passed. Once again, because the signal bandwidth, for instance, is 0.1 Hz, the bandwidth efficiency is 1.73 b/s/Hz. However, because of the higher entropy of the signal y(t), the minimum S/N is now 100 and E_{b}/N₀=30 dB (compared to 34 dB for x(t)).

Finally, the combination signal z(t)=x(t)×y(t) is used with the delay communication method with the same parameters. This combination signal z(t) is an example of a positive entropy, baseband signal that is modulated onto a higher frequency positive entropy signal. The calculated entropy of z(t) is 2.76 bits, which is the sum of the entropies of x(t) and y(t). The bandwidth of signal and noise is once again 0.1 Hz. The minimum S/N for error free communication in this case is 22.7 and E_{b}/N₀=23.5 dB, reflecting the larger entropy of the signal z(t).

The maps described above are useful for illustrating the general concepts of the delay communication method, but they do not have as high bandwidth efficiencies as possible according to the present invention. Higher bandwidth efficiencies are seen, for example, in chaotic flows.

A chaotic system for use in accordance with the invention typically has a well-defined and controllable bandwidth. For example, a 6-dimensional version of a Rossler-like system is described by

$$\begin{matrix}\frac{ⅆ {x}_{1}}{ⅆ t} = - α ( 0.02 {x}_{1} + 0.5 {x}_{2} + {x}_{3} + 0.5 \vert {x}_{4} \vert ) \\ \frac{ⅆ {x}_{2}}{ⅆ t} = - α ( - {x}_{1} + 0.02 {x}_{2} + {x}_{6} ) \\ \frac{ⅆ {x}_{3}}{ⅆ t} = - α ( - g ( {x}_{1} ) + {x}_{3} ) & ( 8 ) \\ \frac{ⅆ {x}_{4}}{ⅆ t} = - 10 {ατ}_{f} ( 0.05 {x}_{4} + 0.5 {x}_{5} + {x}_{6} ) \\ \frac{ⅆ {x}_{5}}{ⅆ t} = - 10 {ατ}_{f} ( - {x}_{4} - 0.13 {x}_{5} ) \\ \frac{ⅆ {x}_{6}}{ⅆ t} = - 10 {ατ}_{f} ( - g ( {x}_{4} ) + {x}_{6} ) & ( 9 ) \\ g ( x ) = \{ \begin{matrix}0 & x < 3 \\ 15 ( x - 3 ) & x \geq 3\end{matrix} \} \\ {τ}_{f} = 1 + γ ( {x}_{2} + 1.75 ) & ( 10 )\end{matrix}$$

where α, which sets the overall time scale of the oscillator, is 1. See, e.g., T. L. Carroll, “Chaotic communications that are difficult to detect,” Physical Review E, vol. 67, February pp. 026207, 2003, incorporated herein by reference. Eq. (9) is a Rossler oscillator whose time constant is modulated by τ_{f}, which is a function of x₂ from Eq. (8). See, e.g., O. E. Rossler, “The Chaotic Hierarchy,” Z. Naturforsch., vol. 38a, July, pp. 788-801, 1983, incorporated herein by reference. Eq. (8) is a low frequency nonlinear oscillator driven by the higher frequency Rossler system of Eq. (9). The effect of the variable time constant τ_{f} is to broaden the power spectrum of the Rossler system of Eq. (9) by an amount determined by the factor γ in Eq. (10). For the example presented here, γ=0.3. Equations (8-10) are numerically integrated with a 4th order Runge-Kutta integration routine with a time step of 0.04.

The transmitted signal is derived from

$${x}_{t} ( t ) = \frac{{x}_{5} ( t )}{\sqrt{{{x}_{4} ( t )}^{2} + {{x}_{5} ( t )}^{2}}} \qquad ( 11 )$$

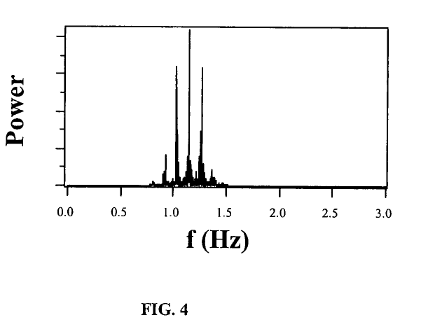

which is the sine of the phase angle of the Rossler attractor. The signal xₜ(t) has a constant envelope. FIG. 4 is a power spectrum of xₜ(t) from the flow of Eqs. (8-11), which has a bandwidth of 0.25 Hz. The delay communication signal ξₜ(t) (defined, by way of example, in Eq. (2)) is optionally also bandpass filtered by, for instance, a digital FIR filter with a bandwidth of 0.25 Hz to insure a well defined bandwidth.

The Rossler signal is transmitted with, for instance, three, four, five, or more delays. The possible delays ranged from 0.4 s (10 points) to 40 s (1000 points), and are spaced, for instance, every 0.4 s (10 points), for 100 possible delay values. The transmitted delays are detected by computing the cross-correlation of a stored reference signal with the transmitted signal. For three delays, Eq. (3) gives a total of 161,700 possible delay combinations. For example, 100 points are transmitted using 4.0 s for each data interval. The bandwidth efficiency is therefore log₂(161,700)/(4 s)/(0.25 Hz), or 17.3 bits/s/Hz. When four delays are used, there are 3,921,225 possible combinations, for a bandwidth efficiency of 21.9 bits/s/Hz, and five delays give 75,287,520 possible combinations, or 26.1 bits/s/Hz. In terms of practical detection times, the maximum number of delays is dependent on processor speed and/or power. More powerful or speedier general processors or specialized processors enable a greater number of delays to be used, thereby yielding a larger symbol set or constellation of symbols available for conveying information than would otherwise be possible.

The finite bandwidth of the channel makes it impossible to instantly change the transmitted signal from one interval to the next, so the signal from one interval will interfere with the signal in the next interval. This inter-symbol interference is accounted for, in an embodiment of the invention, in order to insure an accurate comparison of the transmitted signal with the reference signals.

In order to simulate a narrow band channel, the signal ξ(t) is filtered by a finite impulse response (“FIR”) filter. A FIR filtered signal y(t) is given by

$$y ( t ) = {\sum }_{i = 0}^{N - 1} {α}_{i} x ( t - ⅈτ ) \qquad ( 12 )$$

where x(t) is the input signal, the filter has N stages, and r is the time step for the digitized time series. N is set to, for instance, 50.

Each data interval (symbol) is L points long. Because the FIR filter is a weighted sum of the previous points in the time series, the filtered signal from every data interval contains a contribution from the previous data interval. In creating the reference signal, it is optional, though advantageous, to take into account this inter-symbol interference. Because the FIR filter is linear, each delayed data segment is pre-filtered individually before adding them together to form the reference signal. For n delays, the reference signal is

$$\begin{matrix}{ψ}_{ref\_f} ( i ) = {Ψ}_{0} ( i ) + {\sum }_{j = 0}^{n} {x}_{jf} ( i ) & ( 13 ) \\ {Ψ}_{0} ( i ) = \{ \begin{matrix}{\sum }_{j = 0}^{L - i} {α}_{j} {ψ}_{ref\_f} ( - j - 1 ) & i < L \\ 0 & i \geq L\end{matrix} \} \\ {x}_{kf} ( i ) = \{ \begin{matrix}{\sum }_{j = 0}^{i} {α}_{j} x ( j - ⅈ + k τ ) & i < L \\ {\sum }_{j = 0}^{L} {α}_{j} x ( j - ⅈ + k τ ) & i \geq L\end{matrix} \} & ( 14 )\end{matrix}$$

where the α's are the FIR filter coefficients, and Ψ₀ is the inter-symbol interference term, i.e., the contribution to the signal from the previous interval. The set of signals x_{kf}(i) is the set of pre-filtered delayed data segments.

An alternative solution to addressing inter-symbol interference includes transmitting filler between symbols in the transmitted signal. Another solution to addressing inter-symbol interference includes transmitting a known symbol between symbols in the transmitted signal. The latter solution effectively elongates each symbol in the transmitted signal transmitted across the communications channel.

Assuming a good estimate of the channel filtering, the transmitted signal and the reference signal is started with the same initial condition so that the reference filter is properly initialized. For completeness, a case below is considered where the reference filter is not a perfect match for the channel filter.

To illustrate a sample communication, the signal of Eq. (11) is transmitted with three, four, or five delays. The channel bandwidth is, for example, 0.25 Hz. The reference signal is equalized as described above. Gaussian white noise with a bandwidth of, for instance, 0.25 Hz is added to the transmitted signal.

In this example, for all delay combinations, the smallest value of E No for which error free communication is possible is 48 dB (wherein the S/N is 26). Replacing the chaos signal with filtered Gaussian noise results in the same value of E_{b}/N₀. The fact that the minimum E_{b}/N₀ is the same for three, four, or five delays suggests that the performance of this system is limited by the filtering.

When the signal bandwidth, noise bandwidth and simulation bandwidth are all the same, the minimum value of E_{b}/N₀ for a given bandwidth efficiency (bits/sec/Hz) is given by Eq. (6). For the communication system here, Eq. (6) does not apply, since the simulation bandwidth is not the same as the noise or signal bandwidth. In a standard communication system based on a periodic carrier, the carrier adds no information, so a baseband analysis could be used in which only the modulating signal is considered. In the instant invention, a separation into baseband signal and carrier is not possible because the carrier also contains some information.

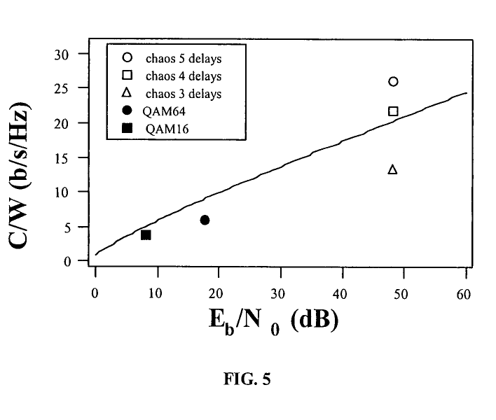

FIG. 5 shows the bandwidth efficiencies for various communications systems. For three delays, the bandwidth efficiency communication for the above-described illustrative system is 17.3 bits/4 sec/0.25 Hz=17.3 b/s/Hz. For four delays, the efficiency is 21.9 b/s/Hz, and for five delays, the efficiency is 26.1 b/s/Hz. These numbers are plotted in FIG. 5, along with the relation from Eq. (6), the theoretical maximum for signals where signal bandwidth is equal to or substantially equal to noise bandwidth, which in turn is equal to or substantially equal to simulation bandwidth. It can be seen that for four or five delays, the bandwidth efficiency of this method exceeds the efficiency theoretically possible according to Eq. (6), but there is no contradiction because Eq. (6) does not apply in this situation. From Eq. (5), the maximum number of bits that can be transmitted in a data interval of length L=100 for a S/N of 26 is 100 samples×4.7 bits/sample=470 bits, which is much greater than what is actually being sent. So, there is no contradiction with information theory.

FIG. 5 also shows the theoretical bandwidth efficiencies for 16 and 64 level quadrature amplitude modulation (e.g., 16 QAM and 64 QAM), which are existing high bandwidth efficiency communication methods.

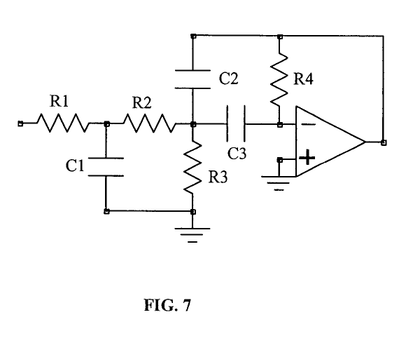

In a real communication system, there is difficulty in accurately matching the channel filter for equalization purposes. The effects of imperfect filtering are illustrated as follows. The Rossler signal with three or four delays is sent through a 12 bit digital-to-analog converter to produce an analog signal. The analog signal is optionally filtered with the filter in FIG. 7, which, by way of example, is a second order bandpass filter with a Q=4 and a center frequency of 17,580 Hz. The components of the bandpass filter shown in FIG. 7 have the following illustrative values: R1=1 kΩ, R2=3621 Ω, R3=7242 Ω, R4=116.8 Ω, C1=0.1 μF, and C2=C3=0.01 μF. The filtered signal is digitized by, for instance, a different computer. Optionally, if the clock rates of the computer associated with the encoder side and the computer associated with the decoder side do not match exactly, a separate sync signal is also transmitted to indicate the beginning of each data interval.

Several different lengths L for each data interval are used. To perform equalization of the digitized signal, a 100 stage FIR filter, for example, is used. The filter coefficients are found by minimizing the difference between filtered and unfiltered versions of the same chaotic Rossler signal.

For both three and four delays, for example, the minimum data interval L for which error free communication is possible is 300 points. The data rate for the D/A converter is 400,000 pts/sec, so a 300 point data interval is 7.5×10⁻⁴ s, and the signal bandwidth is 4000 Hz. For three delays, the resulting bandwidth efficiency with the fitted filter is 5.7 b/s/Hz, and for four delays the efficiency is 7.3 b/s/Hz. The same bandwidth efficiencies are seen when a filtered Gaussian noise signal is used instead of the chaos. Errors in the equalization filter (and noise introduced by D/A and A/D converters) reduce the bandwidth efficiency.

Combining delayed signals, as described above, creates a large number of symbols, making high bandwidth efficiencies possible. But, detecting these symbols by cross-correlating with every possible reference symbol is a very slow process, depending on available processor speed or power. In a less processor-intensive embodiment of the invention, the transmitted symbols are detected with much less computation by doing a least squares fit to the reference symbols. In this case, the transmitted signal is modeled by

$${ξ}_{t} ( t ) = {β}_{0} x ( t ) + {\sum }_{i = 1}^{m} {β}_{i} x ( t + {τ}_{i} ) \qquad ( 15 )$$

where the β's are weighting coefficients that must be fit, and the sum extends from i=1 to i=100 for 100 possible delay values. A singular value decomposition is used to do the fitting. Equalization is performed as above, assuming a perfect filter match. See, e.g., W. H. Press, B. P. Flannery, S. A. Teukolsky, and W. T. Vetterling, Numerical Recipes. New York: Cambridge University Press, 1990, incorporated herein by reference.

The least squares fitting procedure is faster but less robust than using cross-correlations to find the delays. For three delays and a 100 point (4 s) data interval, for example, the minimum E_{b}/N₀ for error free communication is 94 dB, compared to 57 dB for the cross correlation method. If an 800 point (32 s) data interval is used, the minimum E_{b}/N₀ is 48 dB, but the bandwidth efficiency in this case is 2.1 b/s/Hz. Similar results are seen for four, five, or six delays. For six delays, a bandwidth efficiency of 30 dB requires an E_{b}/N₀ of 94 dB, while an efficiency of 3.7 b/s/Hz requires 58 dB. As can be seen, the least squares fitting method is much faster than the cross correlation method, but it is also much less noise robust.

Utilizing a carrier signal with a positive entropy makes it possible to increase the amount of information transmitted in a given bandwidth. In some cases, the amount of information in bits/second/Hz appears to exceed the theoretical channel capacity, but only because the well known theoretical limit (Eq. (6)) is derived for the special case of signal bandwidth=noise bandwidth=simulation bandwidth. Achieving large bandwidth efficiencies depends on accurately matching the filtering effects of the channel; filter mismatch reduces the bandwidth efficiency. Detection can be slow when there are many symbols, but there are other detection techniques that can speed up the detection process, although they require a larger signal to noise ratio than the straightforward method of computing cross-correlations.

It should be understood that other signals with positive entropy, such as noise signals, are also useful information carrier signals. For example, a noise signal for use as a carrier is sampled from an antenna, from a electrical circuit, and/or from pseudo-noise generated by a computer algorithm.

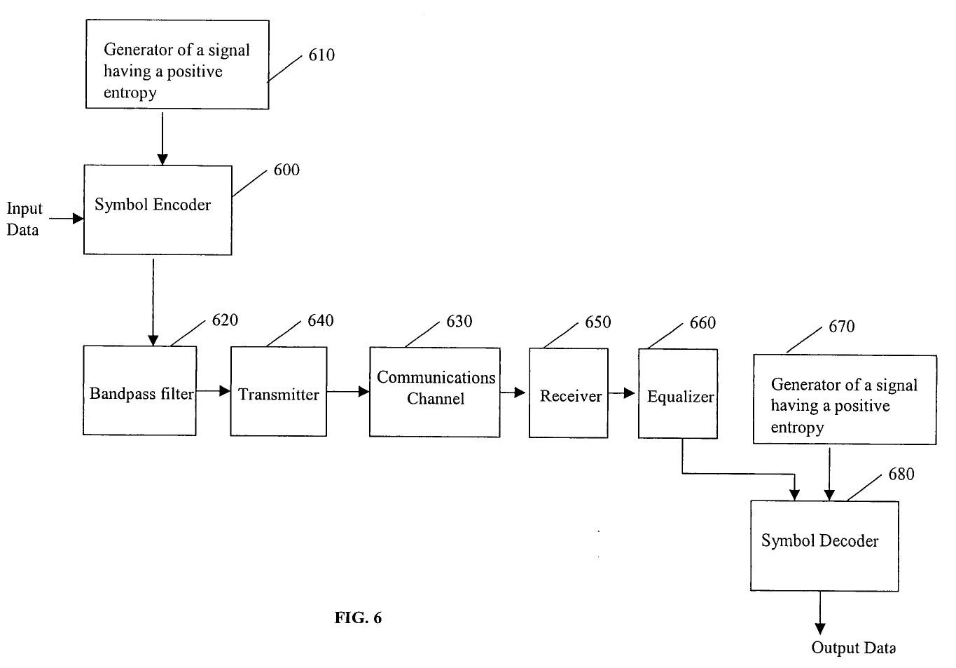

FIG. 6 shows a block diagram of an exemplary architecture of a communications system in accordance with the present invention. Symbol encoder 600 receives data, to be encoded. Generator 610 transmits a carrier signal having positive entropy x(t) to the symbol encoder 600. The symbol encoder 600 encodes the data by representing the data as a sum of the carrier signal having positive entropy and a plurality of delayed versions of the carrier signal having positive entropy, as described above. The encoded data is then optionally passed through a filter, such as a bandpass filter 620, so that the bandwidth of the encoded data is less than or substantially equal to the bandwidth of a communications channel 630 through which the encoded data passes. For instance, if the carrier signal x(t) occupies a greater bandwidth than the communications channel 630, then the filter 620 is advantageous. A transmitter 640 transmits the encoded data through the communications channel 630.

A receiver 650 receives the encoded data from the communications channel 630 and transmits the encoded data to an optional equalizer 660, the operation of which is as described above. The outputs of the equalizer 660 and a generator 670 of a signal having positive entropy are inputted to a symbol decoder 680. The output of generator 670 and the output of generator 610 are substantially similar, and preferably identical. The symbol decoder 680, as described above, identifies each symbol in the original data by determining the delayed versions of the carrier signal having positive entropy that were added to the carrier signal having positive entropy and the delay values of those delayed versions.

If the carrier signal having positive entropy being used is a noise signal, a copy of the noise signal is stored as a reference at the encoder side as well as at the decoder side. If the carrier signal having positive entropy being used is a chaotic signal, a copy of the chaotic signal can be stored as a reference on the encoder and/or decoder sides, or the chaotic signal can be derived from an equation and defined initial conditions at the encoder and/or decoder sides.

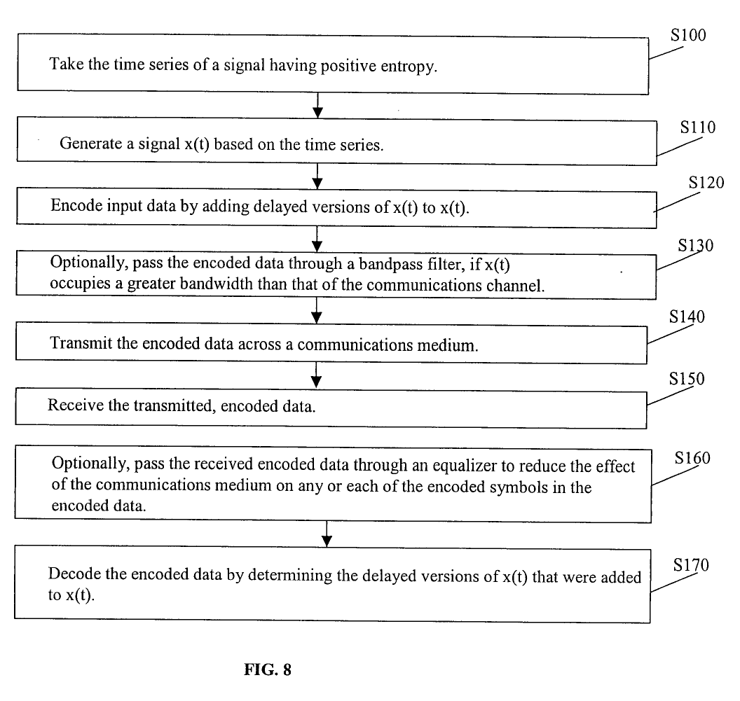

FIG. 8 is an illustrative flow chart of an encoding and/or decoding method in accordance with the instant invention. Optionally, one or more of the steps of the flow chart at least partially form the basis of computer-executable instructions in accordance with the present invention. In Step S100, the time series of a signal having positive entropy is taken. In Step S110, a carrier signal having positive entropy x(t) is generated based on the time series of Step S1100. In Step S120, input data is encoded by encoder 600 by adding x(t) to delayed versions of x(t). In optional Step S130, the encoded data is passed through a filter 620, for instance, if x(t) occupies a greater bandwidth than that of the communications channel or medium 630. In Step S140, the encoded data is transmitted by transmitter 640 across the communications channel 630. In Step S150, the transmitted, encoded data is received by the receiver 650 from the communications channel 630. In Step S160, the received encoded data is optionally passed through an equalizer to reduce the effect of the communications medium on any or each of the encoded symbols in the encoded data. In Step S170, each symbol in the encoded data is decoded by decoder 680 by determining the delayed versions of x(t) that were added to x(t) and the delay values for each of the delayed versions.

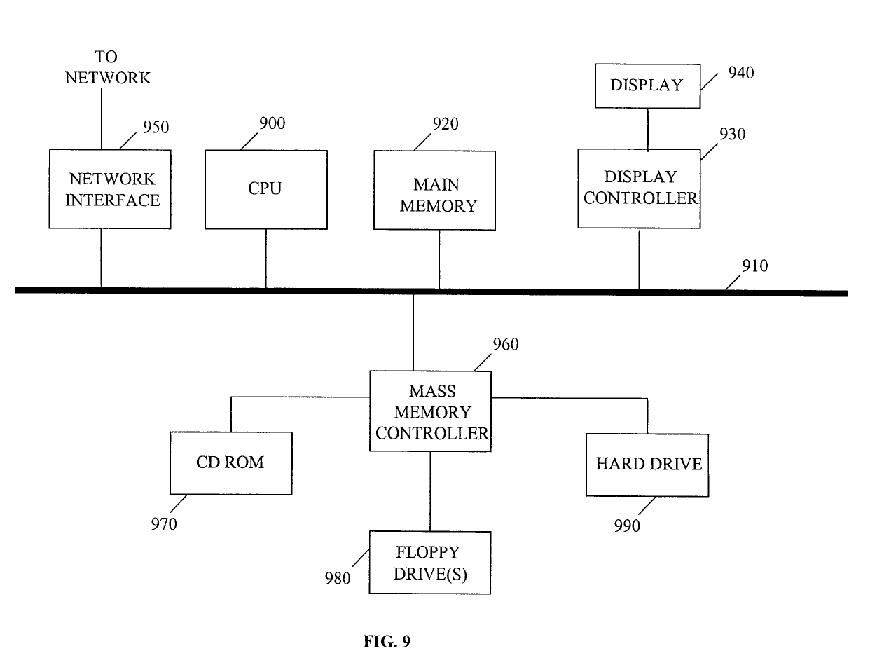

FIG. 9 is a block diagram of an exemplary architecture of a computer, for example, that executes one or more programs or instruction sets in accordance with the instant invention. The computer suitable for interaction with the interactive platform of the invention includes a CPU 900 connected to bus 910. The computer includes a main memory 920, a display controller 930 with accompanying display 940. A memory controller 960 interfaces at least one of a plurality of storage devices such as a CD ROM 970, a floppy drive 980, and a hard drive 990. A network interface card 950 permits access to a network for the computer. Main memory 920 optionally includes volatile memory. For instance, CPU 900 executes computer-readable instructions implementing the method steps or functions described above.

Obviously, many modifications and variations of the present invention are possible in light of the above teachings without departing from the true scope and spirit of the invention. It is therefore to be understood that the scope of the invention should be determined by referring to the following appended claims.

1. A communications method comprising:
providing (i) a first signal having a positive entropy and (ii) a plurality of delayed versions of the first signal, each delayed version of the plurality of delayed versions comprising a plurality of available values;
encoding data comprising a symbol by representing the symbol as a plurality of delay values, wherein each of said plurality of delay values comprises an available value of the plurality of available values for each delayed version of the plurality of delayed versions; and
transmitting the encoded data across a communications channel.

2. The communications method according to claim 1, further comprising:
summing the first signal having positive entropy and the plurality of delayed versions of the first signal, the plurality of delayed versions of the first signal comprising the plurality of delay values for the symbol.

3. The communications method according to claim 1, further comprising:
decoding the encoded data by identifying each transmitted, delayed version of the plurality of delayed versions of the first signal; and
determining a transmitted delay value of the plurality of delay values for each identified delayed version.

4. The communications method according to claim 1, wherein the first signal comprises one of a chaotic signal, a noise signal, and a positive entropy, baseband signal modulated onto a positive entropy signal having a higher frequency than the baseband signal.

5. The communications method according to claim 1, wherein said decoding step comprises:
generating a second signal substantially similar to the first signal,
summing the second signal and a plurality of reference delays; and
maximizing a cross-correlation between the encoded data and the sum of the second signal and the plurality of reference delays.

6. The communications method according to claim 5, further comprising:
compensating the plurality of reference delays for degradation by the communications channel of the plurality of delayed versions of the first signal.

7. The communications method according to claim 1, wherein said decoding step comprises:
generating a weighted third signal substantially similar to the first signal,
summing the weighted third signal and a plurality of weighted reference delays; and
performing a least squares fit between the encoded data and the sum of the third signal and the plurality of weighted reference delays.

8. The communications method according to claim 7, further comprising:
compensating the plurality of weighted reference delays for degradation by the communications channel of the plurality of delayed versions of the first signal.

9. A communications apparatus comprising:
means for providing (i) a first signal having a positive entropy and (ii) a plurality of delayed versions of the first signal, each delayed version of the plurality of delayed versions comprising a plurality of available values;
means for encoding data comprising a symbol by representing the symbol as a plurality of delay values, wherein each of said plurality of delay values comprises an available value of the plurality of available values for each delayed version of the plurality of delayed versions; and
means for transmitting the encoded data across a communications channel.

10. The communications apparatus according to claim 9, further comprising:
means for summing the first signal having positive entropy and the plurality of delayed versions of the first signal, the plurality of delayed versions of the first signal comprising the plurality of delay values for the symbol.

11. The communications apparatus according to claim 9, further comprising:
means for decoding the encoded data by identifying each transmitted delayed version of the plurality of delayed versions of the first signal; and
means for determining a transmitted delay value of the plurality of delay values for each identified, delayed version.

12. The communications apparatus according to claim 9, wherein the first signal comprises one of a chaotic signal, a noise signal, and a positive entropy, baseband signal modulated onto a positive entropy signal having a higher frequency than the baseband signal.

13. The communications apparatus according to claim 9, wherein said decoding means comprises:
means for generating a second signal substantially similar to the first signal,
means for summing the second signal and a plurality of reference delays; and
means for maximizing a cross-correlation between the encoded data and the sum of the second signal and the plurality of reference delays.

14. The communications apparatus according to claim 13, further comprising:
means for compensating the plurality of reference delays for degradation by the communications channel of the plurality of delayed versions of the first signal.

15. The communications apparatus according to claim 9, wherein said decoding means comprises:
means for generating a weighted third signal substantially similar to the first signal,
means for summing the weighted third signal and a plurality of weighted reference delays; and
means for performing a least squares fit between the encoded data and the sum of the third signal and the plurality of weighted reference delays.

16. The communications apparatus according to claim 15, further comprising:
means for compensating the plurality of weighted reference delays for degradation by the communications channel of the plurality of delayed versions of the first signal.

17. A communications device comprising:
a symbol encoder for receiving data comprising a symbol and for receiving a first signal having a positive entropy, the symbol encoder adding to the first signal a plurality of delayed versions of the first signal, each delayed version of the plurality of delayed versions comprising a plurality of available values, the symbol being represented by a set of delay values, a delay value of the set of delay values comprising an available value of the plurality of available values for the each delayed version of the plurality of delayed versions; and
a transmitter for receiving the encoded data from the symbol encoder and for transmitting the encoded data.

18. The communications device according to claim 17, wherein the first signal having positive entropy comprises one of a chaotic signal, noise signal, and a positive entropy, baseband signal modulated onto a positive entropy signal having a higher frequency than the baseband signal.

19. The communications device according to claim 18, wherein the chaotic signal comprises one of a Lorenz system-generated chaotic signal and a Rossler system-generated chaotic signal.

20. A communications device for receiving encoded data, the communications device comprising:
a receiver for receiving a first signal having positive entropy added to a plurality of delayed versions of the first signal, each delayed version of the plurality of delayed versions comprising a plurality of available values, wherein encoded data comprises a symbol, the symbol being represented by a plurality of delay values, a delay value of the plurality of delay values comprising an available value of the plurality of available values for the each delayed version of the plurality of delayed versions; and
a symbol decoder for receiving the encoded data from said receiver, the symbol decoder
for summing a second signal, substantially similar to the first signal, and a plurality of reference delays, and
for maximizing a cross-correlation between the encoded data and the sum of the second signal and the plurality of reference delays.

21. The communications device according to claim 20, wherein the first signal having positive entropy comprises one of a chaotic signal, noise signal, and a positive entropy, baseband signal modulated onto a positive entropy signal having a higher frequency than the baseband signal.

22. The communications device according to claim 21, wherein the chaotic signal comprises one of a Lorenz system-generated chaotic signal and a Rossler system-generated chaotic signal.

23. The communications device according to claim 20, further comprising an equalizer communicating with said receiver and with said symbol decoder.

24. A communications device for receiving encoded data, the communications device comprising:
a receiver for receiving a first signal having positive entropy added to a plurality of delayed versions of the first signal, each delayed version of the plurality of delayed versions comprising a plurality of available values, wherein encoded data comprises a symbol, the symbol being represented by a plurality of delay values, a delay value of the plurality of delay values comprising an available value of the plurality of available values for the each delayed version of the plurality of delayed versions; and
a symbol decoder for receiving the encoded data from said receiver, the symbol decoder
for summing a third signal, being a weighted version of the first signal, and a plurality of weighted reference delays, and
for performing a least squares fit between the encoded data and the sum of the third signal and the plurality of weighted reference delays.

25. The communications device according to claim 23, wherein the first signal having positive entropy comprises one of a chaotic signal, noise signal, and a positive entropy, baseband signal modulated onto a positive entropy signal having a higher frequency than the baseband signal.

26. The communications device according to claim 25, wherein the chaotic signal comprises one of a Lorenz system-generated chaotic signal and a Rossler system-generated chaotic signal.

27. The communications device according to claim 24, further comprising an equalizer communicating with said receiver and with said symbol decoder.
